(19) United States
(12) Patent Application Publication
(10) Pub. No.: US 2021/0136299 A1
(43) Pub. Date: May 6, 2021

(54) BACKSIDE ILLUMINATED IMAGE SENSORS WITH PIXELS THAT HAVE HIGH DYNAMIC RANGE, DYNAMIC CHARGE OVERFLOW, AND GLOBAL SHUTTER SCANNING

(71) Applicant: SEMICONDUCTOR COMPONENTS INDUSTRIES, LLC, Phoenix, AZ (US)

(72) Inventor: Jaroslav HYNECEK, Allen, TX (US)

(73) Assignee: SEMICONDUCTOR COMPONENTS INDUSTRIES, LLC, Phoenix, AZ (US)

(21) Appl. No.: 17/147,194

(22) Filed: Jan. 12, 2021

Related U.S. Application Data
(62) Division of application No. 16/502,349, filed on Jul. 3, 2019.
(60) Provisional application No. 62/797,621, filed on Jan. 28, 2019.
(60) Provisional application No. 62/835,182, filed on Apr. 17, 2019.

(51) Int. Cl. H04N 5/355; H04N 5/378; H04N 5/369; H01L 27/146

(52) U.S. Cl. CPC H04N 5/3559; H01L 27/14616; H04N 5/379; H04N 5/378

(57) ABSTRACT

Image sensors may include backside illuminated global shutter pixels that are implemented using stacked substrates. To provide high dynamic range in the pixels, only a predetermined portion of charge that has been generated in the pixel photodiodes is kept and stored in the pixel photodiodes when the pixels are illuminated by high light levels. In the low light level illumination conditions, all of the accumulated charge is stored in the pixel photodiodes, thereby preserving high sensitivity and low noise. Dynamic charge overflow may be used to increase the high dynamic range. To achieve low noise operation in a global shutter scanning mode, dynamic charge overflow may be combined with correlated double sampling techniques. Dynamic charge overflow may be achieved using a transistor-based overflow device or using an n-p-n based overflow device.

### CROSS-REFERENCE TO RELATED APPLICATIONS

This application is a division of U.S. Non-provisional patent application Ser. No. 16/502,349, filed Jul. 3, 2019, which claims the benefit of U.S. Provisional Patent Application No. 62/797,621, filed on Jan. 28, 2019, and the benefit of U.S. Provisional Patent Application No. 62/835,182, filed on Apr. 17, 2019, which are all hereby incorporated by reference herein in their entireties.

### BACKGROUND

This relates generally to imaging sensors and, more particularly, to high dynamic range (HDR) complementary metal-oxide-semiconductor (CMOS) image sensor arrays that are illuminated from the backside of the substrate and operate in a global shutter (GS) scanning mode.

Modern electronic devices such as cellular telephones, cameras, and computers often use digital image sensors. Image sensors (sometimes referred to as imagers) may be formed from a two-dimensional array of image sensing pixels. Each pixel includes a photosensitive element that receives incident photons (light) and converts the photons into electrical signals. Image sensors are sometimes designed to provide images to electronic devices using a Joint Photographic Experts Group (JPEG) format.

Some conventional image sensors may be able to operate in a high dynamic range (HDR) mode. Image sensors may also operate in a rolling shutter mode or a global shutter mode. Global shutter image sensors typically require an additional charge storage node in each pixel, which consumes a significant portion of the available pixel area and thus increases the cost of the sensors. For high dynamic range sensors, this problem is further exacerbated by additional requirement to store a much larger amount of charge in the pixels.

It would therefore be desirable to be able to provide improved high dynamic range global shutter image sensors.

### BRIEF DESCRIPTION OF THE DRAWINGS

FIG. 1 is a schematic diagram of an illustrative electronic device with an image sensor in accordance with an embodiment.

FIG. 2 is a perspective view of an illustrative image sensor with multiple chips and electrically conductive bonds between the upper chip and middle chip in accordance with an embodiment.

FIG. 3 is a cross-sectional side view of an illustrative global shutter image sensor pixel that includes a pinned photodiode, a global charge transfer gate, a charge storage pinned diode, a charge readout transfer gate, and a floating diffusion that is placed in a p-type doped well in accordance with an embodiment.

FIG. 4 is a potential diagram of the global shutter image sensor pixel of FIG. 3 at various biasing conditions in accordance with an embodiment.

FIG. 5 is a circuit diagram for an illustrative global shutter image sensor pixel that includes an n-channel MOSFET with a threshold adjustment implant that forms a potential barrier for dynamic charge overflow in accordance with an embodiment.

FIG. 6 is a timing diagram showing illustrative operation of the global shutter image sensor pixel of FIG. 5 in accordance with an embodiment.

FIG. 7 is a circuit diagram for an illustrative global shutter image sensor pixel in which additional pixel circuitry is moved from the upper chip in accordance with an embodiment.

FIG. 8 is a timing diagram showing illustrative operation of the global shutter image sensor pixel of FIG. 7 in accordance with an embodiment.

FIG. 9 is a cross-sectional side view of an illustrative global shutter image sensor pixel with dynamic charge overflow in accordance with an embodiment.

FIG. 10 is a potential diagram of the global shutter image sensor pixel of FIG. 9 in accordance with an embodiment.

FIG. 11 is a graph of the detected charge versus the output voltage generated by a global shutter image sensor pixel with dynamic charge overflow in accordance with an embodiment.

FIG. 12 is a cross-sectional side view of an imaging pixel having a dynamic charge overflow device formed from an n-p-n region in accordance with an embodiment.

FIG. 13 is a graph of potential profiles that correspond to the pixel of FIG. 12 in accordance with an embodiment.

FIG. 14 is a diagram showing the pixel circuits associated with the imaging pixel of FIG. 12 in accordance with an embodiment.

### DETAILED DESCRIPTION

The following relates to solid-state image sensor arrays that may be included in electronic devices. Specifically, electronic devices may include High Dynamic Range (HDR) complementary metal-oxide-semiconductor (CMOS) image sensor arrays that are illuminated from the backside of the substrate and operate in a global shutter (GS) scanning mode. An image sensor may include stacked chips to improve image sensor performance.

In order to improve image sensor performance, each imaging pixel in the image sensor may include a charge storing mechanism that enables only a predetermined portion of charge to be stored in the pixels when the pixels are illuminated by a high light level illumination. The remaining charge overflows a dynamically adjusted charge overflow barrier to a capacitor. This type of charge storage may be referred to as dynamic charge overflow (DCO). By using dynamic charge overflow, dynamic range may be increased without increasing pixel size or sacrificing performance. This keeps the pixel size small and thus mitigates the cost increase of the HDR sensor arrays. The high performance of the pixel design is further enhanced by using stacked chips. For example, an image sensor may include two or more chips (e.g., an upper chip, a middle chip, and a lower chip), which allows integrating together the dynamic charge overflow with an in-pixel correlated double sampling (CDS) signal processing technique, leading to low noise HDR performance.

It is also possible to design the global shutter scanned pixel circuit to have detected charge from the pinned photodiode (PPD) be stored on a floating diffusion (FD). The floating diffusion advantageously has a smaller size than the pinned photodiode. However, the floating diffusion may have a larger dark current generation than the pinned photodiode. The larger dark current generation can be overcome by a faster scanning, which reduces the signal charge storage time thus reducing the dark current generated charge contribution to the signal. However, when charge is stored on the FD it is necessary to eliminate kTC reset noise when the FD is reset. This may be accomplished by using active pixel reset (APR), in one example.

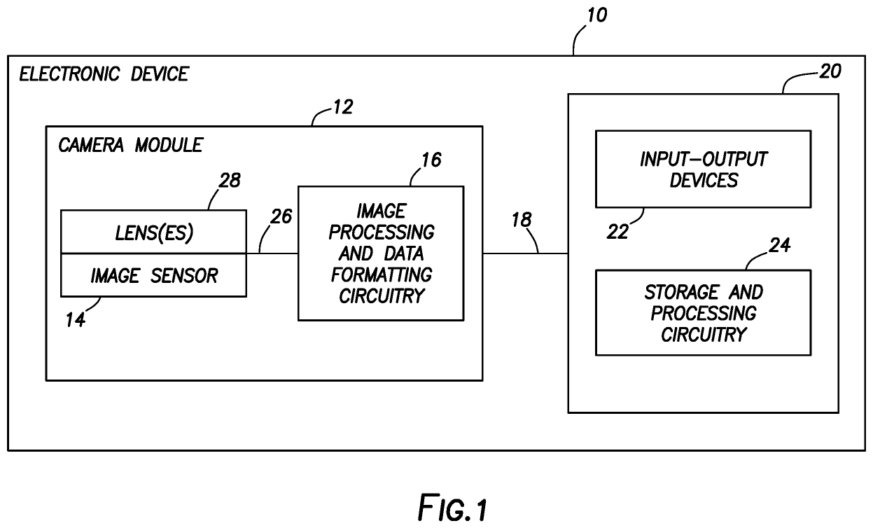

An electronic device with a digital camera module and an image sensor is shown in FIG. 1. Electronic device 10 may be a digital camera, a computer, a cellular telephone, a medical device, or other electronic device. Camera module 12 (sometimes referred to as an imaging device) may include image sensor 14 and one or more lenses 28. During operation, lenses 28 (sometimes referred to as optics 28) focus light onto image sensor 14. Image sensor 14 includes photosensitive elements (e.g., pixels) that convert the light into analog signals that are later converted to digital data. Image sensors may have any number of pixels (e.g., hundreds, thousands, millions, or more). A typical image sensor may, for example, have millions of pixels (e.g., megapixels). As examples, image sensor 14 may include bias circuitry signal buffering circuits (e.g., source follower and load circuits), sample and hold circuitry, correlated double sampling (CDS) circuitry, amplifier circuitry, analog-to-digital (ADC) converter circuitry, data output circuitry, memory (e.g., data buffering circuitry), address circuitry, etc.

Still and video image data from image sensor 14 may be provided to image processing and data formatting circuitry 16 via path 26. Image processing and data formatting circuitry 16 may be used to perform image processing functions such as automatic focusing functions, depth sensing, data formatting, adjusting white balance and exposure, implementing video image stabilization, face detection, etc.

Image processing and data formatting circuitry 16 may also be used to compress raw camera image files if desired (e.g., to Joint Photographic Experts Group or JPEG format). In a typical arrangement, which is sometimes referred to as a system on chip (SOC) arrangement, camera sensor 14 and image processing and data formatting circuitry 16 are implemented on a common integrated circuit chip. The use of a single integrated circuit chip to implement camera sensor 14 and image processing and data formatting circuitry 16 can help to reduce costs. This is, however, merely illustrative. If desired, camera sensor 14 and image processing and data formatting circuitry 16 may be implemented using separate integrated circuit chips.

Camera module 12 may convey acquired image data to host subsystems 20 over path 18 (e.g., image processing and data formatting circuitry 16 may convey image data to subsystems 20). Electronic device 10 typically provides a user with numerous high-level functions. In a computer or advanced cellular telephone, for example, a user may be provided with the ability to run user applications. To implement these functions, host subsystem 20 of electronic device 10 may include storage and processing circuitry 24 and input-output devices 22 such as keypads, input-output ports, joysticks, and displays. Storage and processing circuitry 24 may include volatile and nonvolatile memory (e.g., random-access memory, flash memory, hard drives, solid state drives, etc.). Storage and processing circuitry 24 may also include microprocessors, microcontrollers, digital signal processors, application specific integrated circuits, or other processing circuits.

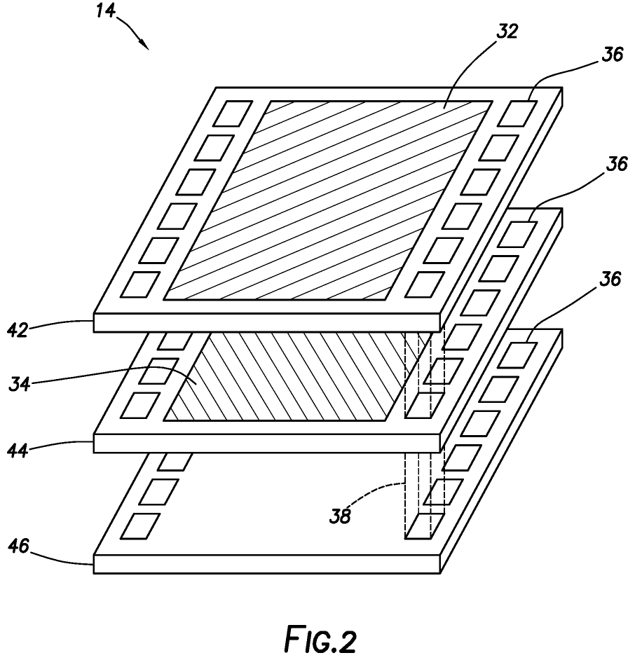

An illustrative image sensor such as image sensor 14 in FIG. 1 is shown in FIG. 2. Image sensor 14 may sense light by converting impinging photons into electrons or holes that are integrated (collected) in sensor pixels. After completion of an integration cycle, collected charge may be converted into a voltage, which may be supplied to the output terminals of the sensor. In CMOS image sensors, the charge to voltage conversions are accomplished directly in the pixels themselves and the analog pixel voltage is transferred to the output terminals through various pixel addressing and scanning schemes. The analog signal may also be converted on-chip to a digital equivalent before reaching the chip output. The pixels may include a buffer amplifier such as a Source Follower (SF) which drives the sense lines that are connected to pixels by suitable addressing transistors. After charge to voltage conversion is completed and the resulting signal is transferred out from the pixels, the pixels may be reset in order to be ready to accumulate new charge. Some pixels may use a Floating Diffusion (FD) as a charge detection node. In these pixels, the reset may be accomplished by turning on a reset transistor that conductively connects the FD node to a voltage reference. In some embodiments, the voltage reference for the FD node may also be the pixel SF drain node. This step removes collected charge from the floating diffusion. However, it also generates kTC reset noise. This kTC reset noise may be removed from the signal using correlated double sampling (CDS) signal processing in order to reduce noise in the sensor. CMOS image sensors that utilize correlated double sampling may use three (3T) or four transistors (4T) in the pixel, one of which serves as the charge transferring (TX) transistor. It is possible to share some of the pixel circuit transistors among several photodiodes, which also reduces the pixel size.

Image sensor 14 may be formed with one or more substrate layers. The substrate layers may be layers of semiconductor material such as silicon. The substrate layers may be connected using metal interconnects. An example is shown in FIG. 2 in which substrates 42, 44, and 46 are used to form image sensor 14. Substrates 42, 44 and 46 may sometimes be referred to as chips. Upper chip 42 may contain pinned photodiodes in pixel array 32. Charge transferring transistor gates may also be included in upper chip 42. To ensure that there is adequate room for the photodiodes in upper chip 42, much of the pixel circuitry for the pixels may be formed in middle chip 44 and lower chip 46. Middle chip 44 may include storage capacitors for storing charge from the photodiode in the upper chip, for example.

Middle chip 44 may be bonded to upper chip 42 with an interconnect layer at every pixel or an interconnect for a group of pixels (e.g., two pixels, three pixels, more than three pixels, etc.). Bonding each pixel in upper chip 42 to corresponding pixel circuitry in middle chip 44 (e.g., floating diffusion to floating diffusion) may be referred to as hybrid bonding. Middle chip 44 and lower chip 46 may not be coupled with hybrid bonding. Only peripheral electrical contact pads 36 of each chip may be bonded together (e.g., chip-to-chip connections 38). Each chip in image sensor 14 may include relevant circuitry. The upper chip may contain pinned photodiodes and charge transferring transistor gates. The upper chip may also contain overflow capacitors, floating diffusion regions, and additional transistors. The middle chip may include capacitors, a source follower transistor, and additional transistors. The bottom chip may include one or more of clock generating circuits, pixel addressing circuits, signal processing circuits such as the CDS circuits, analog to digital converter circuits, digital image processing circuits, and system interface circuits.

The example of FIG. 2 of image sensor 14 having three substrates is merely illustrative. If desired, the image sensor may be formed using a single substrate, using two substrates, or using more than three substrates. Each pair of adjacent substrates may optionally be bonded using hybrid bonding (e.g., a per-pixel metal interconnect layer) or may be boned only at the periphery of the substrates.

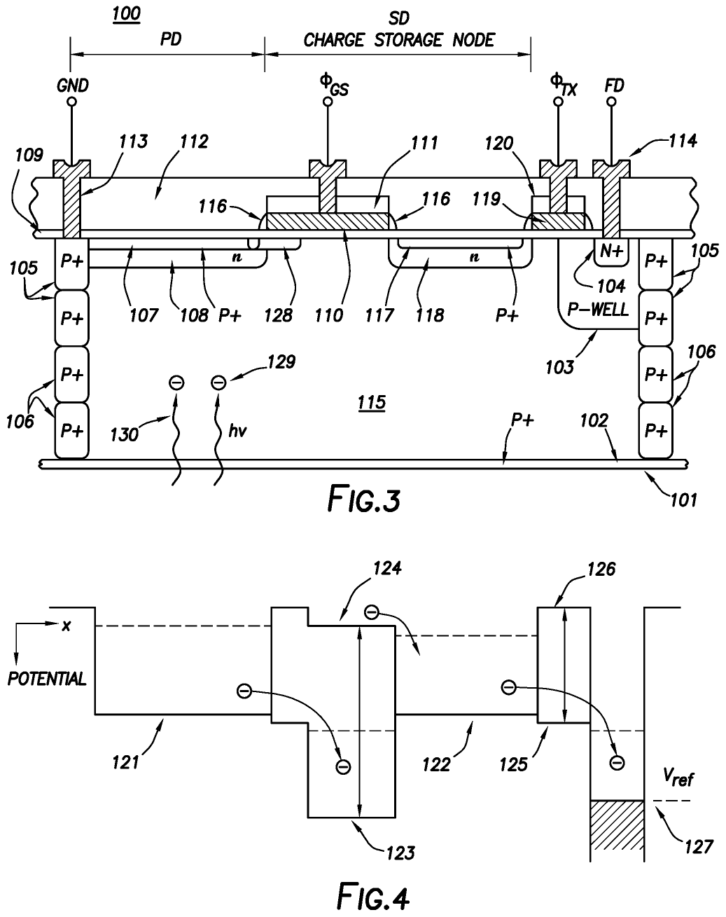

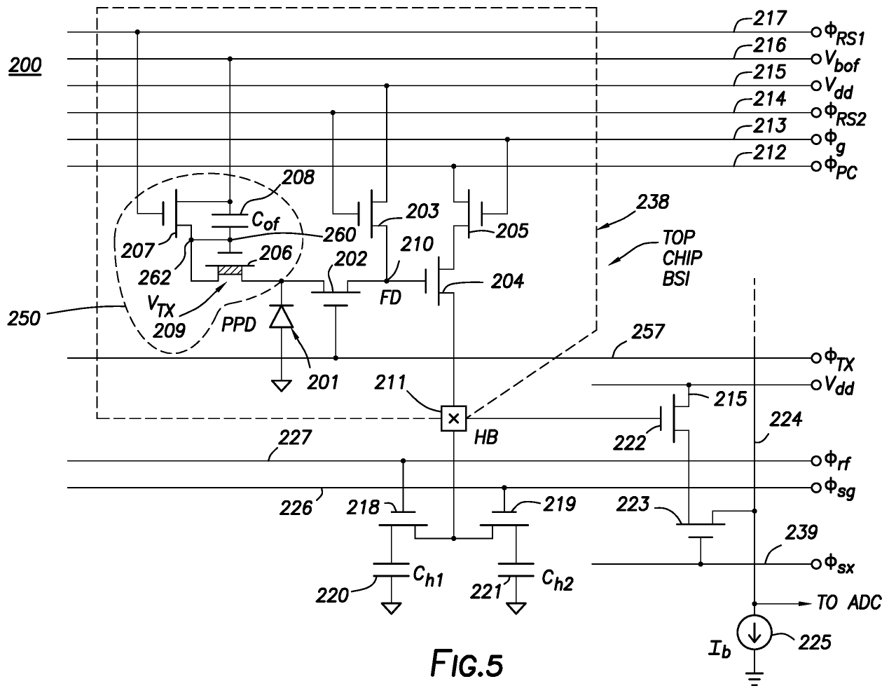

To allow for global shutter operation, each imaging pixel may include a charge storage region in addition to the photodiode. The additional charge storage region may allow for charge to be transferred from all the photodiodes simultaneously. Charge then waits in this storage site for sequential readout in a row-by-row fashion. An example of such a concept is shown in FIGS. 3 and 4.

FIG. 3 is a cross-sectional side view of a global shutter image sensor pixel that includes a pinned photodiode, a global charge transfer gate, a charge storage pinned diode, a charge readout transfer gate, and a floating diffusion that is placed in a p-type doped well. FIG. 4 shows the potential profiles under the different pixel regions of the pixel of FIG. 3 at various biasing conditions.

As shown in FIG. 3, photons 130 generate charge 129 that is collected in the pinned photodiode (sometimes abbreviated as PD or PPD) region. The pinned photodiode region may be adjacent to the charge transfer gate 110 of a corresponding charge transfer transistor. The pixel may be fabricated in a substrate 101 that has a p+ type doped layer 102 deposited on the back surface. P+ type doped layer 102 may prevent the generation of excessive dark current by the interface states. The device substrate further includes epitaxial p-type doped layer 115 situated above the p+ type doped layer 102. The photons 130 that enter this region generate carriers that are collected in the potential well of the photodiode formed in the region 108. The surface of the epitaxial layer 115 is covered by oxide layer 109 that isolates overlying gates (e.g., gate 110) from the substrate. The gates may be poly-silicon gates. The poly-silicon gates may have a masking cap oxide 111 and 120 deposited on top of them that may serve as a patterning hard mask as well as an additional blocking mask for the ion implantation that forms the PPD charge storage region. The PPD may be formed by the n-type doped layer 108 and the p+ type doped potential pinning layer 107. Similar to the p+ type doped layer 102, the p+ type doped potential pinning layer 107 may reduce the interface states generated dark current. In some cases, sidewall spacers 116 may also be incorporated into the structure in order to control the mutual edge positions of the p+ type doped layer 107 and the charge storage layer 108. The contacts to the pixel active regions and ground are realized by metal plugs 114 in openings 113 (sometimes referred to as holes 113) in the deposited Inter Level (IL) oxide layer 112. Several additional IL oxide or oxy-nitride layers may optionally be deposited on the surface of the device to provide metal to metal interconnects isolation. Pixel-to-pixel isolation may be accomplished using pixel separation implants 105 and 106.

To implement global shutter operation, an additional charge storage node is added to the pixel. As shown in FIG. 3, image sensor pixel 100 includes storage diode (SD) well 118 with a corresponding pinning implant 117. These implants may be fabricated at the same time as the regions 108 and 107 in the PD, and may use the same implant doses and energies. A transfer gate TX may also be included for transferring charge from the storage well of SD to the floating diffusion (FD) 104 during row-by-row sequential readout. The FD region 104 is placed in the p-well 103 that may also contain pixel circuit transistors.

The global shuttering is activated by applying a pulse to the global shutter (GS) transfer gate 110. This gate may have an additional implanted region 128 under the portion of its area, which forms the potential barrier preventing charge from flowing back into the PD during charge transfer to the storage region. As shown in FIG. 4, applying the pulse to the global shutter gate results in a potential profile change under this gate from the level 124 to the level 123 and back to the level 124. Charge that has accumulated in the PD potential well 121 during the integration period is thus transferred to the storage well 122. During the readout cycle, the TX gates of the selected row are pulsed, which results in the potential profile under the TX gate changing from the level 126 to the level 125 and back to the level 126. This causes carriers to flow to the FD region and change its potential from its reset level 127. This change may be sensed by the SF transistor and delivered to the array column signal processing circuits located at the periphery of the image sensor array.

As can be seen from the FIG. 3, the pixel charge storage node area (SD) in global shutter image sensor pixel 100 occupies almost the same area of the pixel as the pinned photodiode PD. This may be a disadvantage when the pixel size needs to be reduced.

To improve performance of the pixel shown in FIG. 3, some sensor rows or pixels in a group of pixels may have a shorter integration time than other pixels in the image sensor. This may reduce the amount of charge in those pixels, preventing saturation of the pixels. However, this type of solution requires sacrificing low light level resolution. Performance of the pixel of FIG. 3 may also be improved by using a logarithmic charge to voltage conversion characteristic. However, logarithmic pixels have higher noise and therefore sacrifice low light level performance.

To improve performance of the pixel without sacrificing low light level resolution, a dynamic charge overflow (DCO) structure may be included in the pixel. The DCO structure may allow collection of all charge in the pixel for the low light level illuminations thereby maintaining high low light level performance. For example, below a certain light threshold, all of the light will be collected in the photodiode of the pixel. Above the light threshold, the dynamic charge overflow structure may attenuate (compress) the generated charge. In other words, above the threshold, the dynamic charge overflow structure diverts some (but not all) charge from the photodiode. For example, take an example where the dynamic charge overflow structure compresses charge by a factor of 10. The photodiode therefore is capable of detecting light levels above the threshold that are 10 times higher than if a DCO structure was not present, thereby increasing the dynamic range of the pixel. The pixel size is also not compromised and the sensor resolution with the HDR performance is maintained for large range of illumination levels in the global shutter mode of operation.

Further enhancement of sensor performance may be achieved by implementing the global shutter imaging pixels with stacked chips (e.g., where some of the pixel circuits are located on a second chip, sometimes referred to as a carrier chip). It is thus possible to design the in-pixel correlated double sampling (CDS) circuit where the detected charge is converted to a voltage on the FD node located on the top light sensing chip and through the top chip source followers charge up large capacitors located on the carrier chip. This can be done for the pixel reference signal as well as for the photo charge induced signal thereby allowing the CDS processing scheme to take place, for example, in the ADC converter located at the periphery of the carrier chip. Charging up large value capacitors through the source follower minimizes the deleterious effects of junction leakage currents as well as minimizes kTC reset noise thereby resulting in a low noise floor of the pixel.

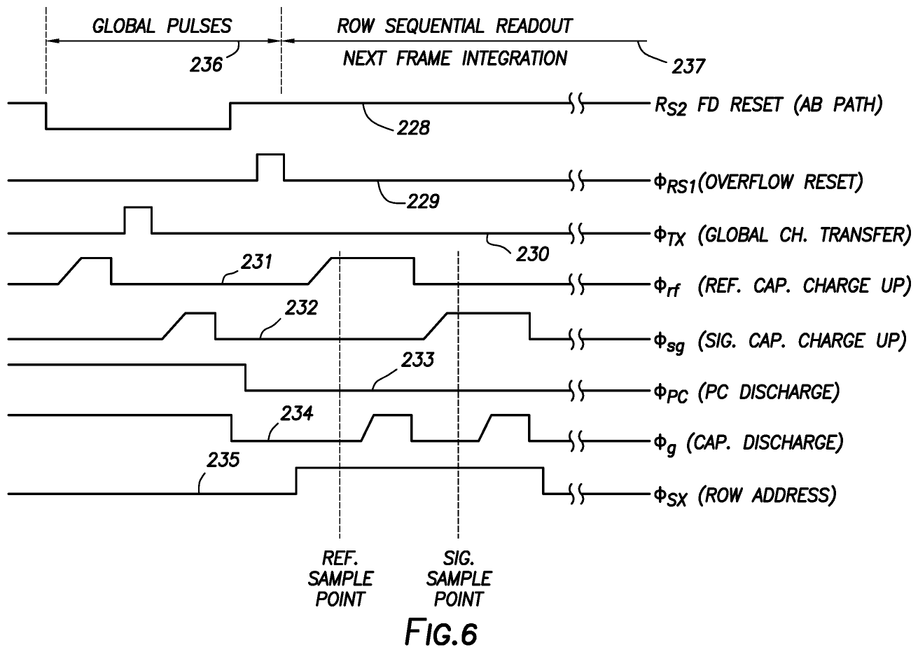

FIG. 5 is a circuit diagram of a global shutter imaging pixel 200 where an n-channel MOSFET with a threshold adjustment implant is used to form a potential barrier for dynamic charge overflow. Charge that overflows this barrier is stored on a capacitor, which is periodically discharged by the reset transistor. The resulting overflow voltage from change on the capacitor is used to provide an additional control of charge overflow barrier height. The GS scanning and the in-pixel CDS operation of this pixel is accomplished by storing charge derived from the FD reference voltage and from the FD signal voltage on capacitors located on the carrier chip (e.g., in deep trench isolation regions). Hybrid bonding is used for the pixel interconnects between the top chip pixels that carry the PPDs and the carrier chip pixels containing the rest of the pixel circuits. FIG. 6 is a timing diagram showing operation of the pixel of FIG. 5.

FIG. 5 shows an illustrative pixel 200 that includes a pinned photodiode (PPD) 201 that collects photon generated charge. The PPD is coupled to a charge overflow circuit 250 that includes transistor 206 with the implanted threshold shift Vtx 209, the overflow charge accumulation capacitor 208 (C_{OF}), and reset transistor 207. Transistor 206 may have a first terminal coupled to the PPD, a second terminal coupled to a node 262 that is interposed between transistor 206 and reset transistor 207, and a gate terminal coupled to a node 260. Capacitor C_{OF} may have first and second plates (sometimes referred to as capacitor terminals). The first plate may be coupled to node 260. The second plate may be coupled to a node that is coupled to reset terminal 207. Nodes 262 and 260 may be electrically connected. With this arrangement, transistor 206 sets the threshold for charge to overflow from the PPD to capacitor C_{OF}. The threshold set by transistor 206 is dependent upon the charge stored in capacitor C_{OF} (e.g., the amount of charge already overflowed into capacitor C_{OF}).

The PPD is further coupled to the global charge transfer transistor 202, floating diffusion (FD) node 210, and source follower (SF) transistor 204 gate. Transistor 202 may also serve as an antiblooming device by directing antiblooming charge to the drain bias line 215 through reset transistor 203. The FD node 210 is reset by the reset transistor 203 to the Vdd bias line 215. The drain of the SF transistor 204 is connected through the transistor 205 to a bias line 212 that may be pulsed to a high or low bias level thus enabling reset of capacitors 220 and 221 when the reset transistor 203 is turned on.

The source of the SF transistor 204 is connected to the hybrid bond pad 211 that provides connection to the circuits on the carrier chip. Hybrid bond pad 211 may sometimes be referred to as a metal interconnect layer (because the hybrid bond pad couples two substrates). The aforementioned components are all located on the top chip 238 (e.g., an upper chip similar to upper chip 42 in FIG. 2) and are supplied with the corresponding driving signals delivered through the lines 212, 213, 214, 216, 217, and 257. The pixel circuit further includes components located on a carrier chip (e.g., a middle chip similar to middle chip 44 in FIG. 2) such as transistors 218 and 219 that direct the reference signal and the photodiode charge induced signal to the storage capacitors 220 and 221. Transistors 218 and 219 are also activated when the transistor 205 is turned off and the voltage signal from the capacitors 220 and 221 is supplied through the SF transistor 222 and the row addressing transistor 223 to the column sense line 224. The column sense line 224 is supplying the bias current to the SF 222 from the current source 225 and delivers the pixel signals to the ADC located at the periphery of the chip together with the current source 225. The CDS signal processing scheme is implemented in the ADC circuits where the pixel reference signal is subtracted from the photon induced signal thereby removing the pixel FD reset kTC noise. The controlling signals to the devices located on the carrier chip are supplied through the lines 215, 226, 227, and 239 correspondingly.

The operation of these pixel circuits may be better understood from the timing diagram provided also in FIG. 6. The diagram consists of two main sections: the global pulses section 236 and the frame charge integration section 237 that also includes the signal readout section. The signal readout section may be shorter than the charge integration section. For simplicity the timing diagram shows the readout only from the first row.

The global charge transfer begins by turning the Rs2 line bias low (see trace 228). This turns the reset transistor 203 off and biases the FD 210 to a floating state. The bias level of the FD is sensed by the SF transistor 204 with its drain connected through the transistor 205 to the line 212 that is biased high as shown by trace 233. The transistor 218 is turned on as shown by the trace 231, which charges up the holding capacitor 220 Ch1 with the reference signal. Next, the transfer gate of transistor 202 is pulsed high and low (see trace 230), which globally transfers charge from all the PPDs to the FDs. The bias of the FDs changes and this is sensed by the SFs, which charges up the holding capacitors 221 (Ch2) to a level determined by the photon generated signal. Charging proceeds through the transistors 219 (that were turned on as indicated by trace 232). The Global Shutter timing cycle is completed by pulsing the overflow reset transistors 207 gate high and low (see trace 229) and turning the transistors 205 gate (see trace 234) and their drains (see trace 233) low. As shown in FIG. 6, charging up pulses (traces 231 and 232) have slow rise times in order to minimize the surge current to capacitors, because the capacitors 220 and 221 are charged all in parallel for the whole array.

In the next step the readout cycle begins by turning the row select transistor 223 on (see trace 235), and the transistor 218 also on (see trace 231). This action supplies the reference signal stored on the capacitor 220 through the SF 222 and the row addressed transistor 223 to the column sense line 224. Column sense line 224 is biased by the current source 225 and supplies this signal to the ADC located at the chip periphery. After the signal is transferred to the ADC and stored there or converted to the digital equivalent, the charge holding capacitor 220 Ch1 is discharged by applying a pulse to the gate of the transistor 205 (see trace 234). The capacitor 220 Ch1 discharge proceeds through the transistor 218, the SF transistor 204, and the transistor 205 to the bias line 212 that has been turned to a low state as shown by trace 233. The low state bias of line 212 may not be all the way to zero (e.g., may be a low bias level that is greater than 0 such as 0.5 V), because this may cause an unwanted electron charge injection from the source-drain junctions of transistors 204 and 205 to the PPD.

The reference signal readout is followed by the photodiode charge generated signal readout stored on the capacitor 221 Ch2 in a similar manner as the reference signal. The transistor 219 is turned on (see trace 232). This action supplies the signal stored on the capacitor 221 through the SF 222 and the row addressed transistor 223 to the column sense line 224. Column sense line 224 supplies this signal again to the ADC located at the chip periphery. After the signal is transferred to the ADC and also stored there or converted to the digital equivalent, the charge holding capacitor 221 Ch2 is discharged by pulsing the gate of the transistor 205 high and low again (see trace 234). The capacitor 221 Ch2 is discharged the same way as the capacitor 220 Ch1 was. The CDS signal processing scheme, subtraction of the reference signal from the FD signal, is realized in the ADC circuits located at the periphery of the carrier chip.

The above described readout for the first row is followed by the readout of the remaining rows in a row-by-row sequential manner until the whole array has been read out. During this time, the next frame of charge is integrated in the PPDs. The readout cycle can be shorter than the charge integration cycle.

Because the capacitor Ch1 220 and Ch2 221 discharge proceeds in a sequential manner, it is not anticipated that large current surges will flow during this process thereby disturbing the power supply or ground bias line potentials. This prevents unwanted noise injection into the signal from these chip power line bounces.

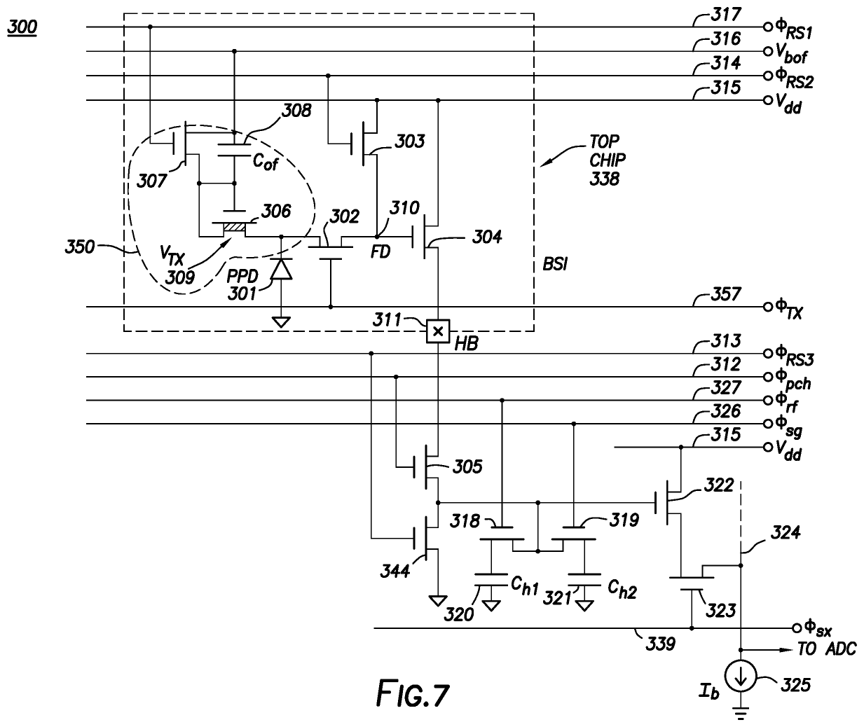

Another embodiment of the present invention is shown in FIG. 7. In this embodiment, the top chip circuit is simplified relative to the circuit of FIG. 5 by removing transistor 205 and placing the reset transistor for resetting the holding capacitors Ch1 and Ch2 on the carrier chip. This keeps the bias of the top chip transistor junctions at a relatively high positive level, thereby preventing any possible charge injection from these junctions into the PPD. The carrier chip may not have a photodiode located in it, which leaves enough room for the additional transistor and the holding capacitors.

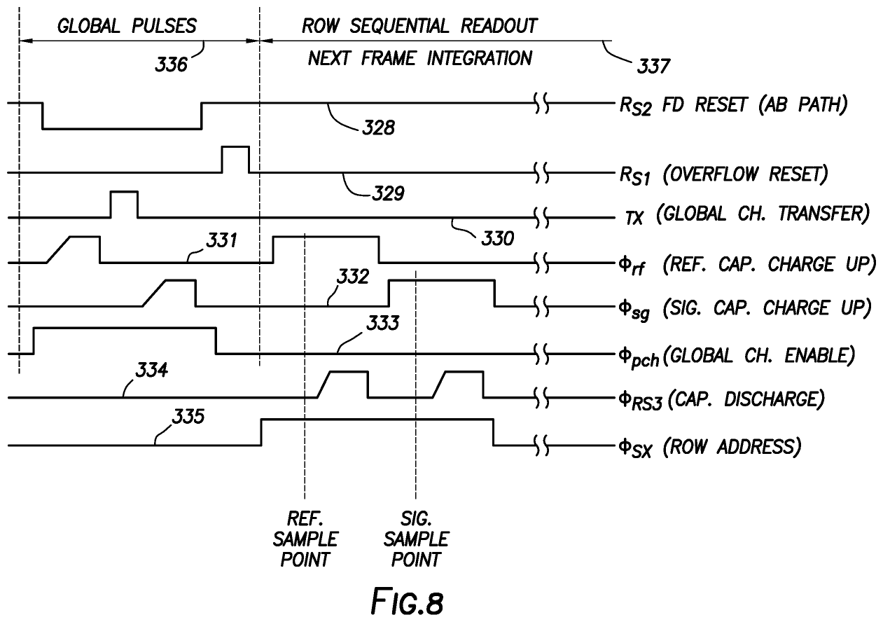

A pixel circuit diagram of this global shutter imaging pixel is shown in FIG. 7. A corresponding timing diagram is shown in FIG. 8. FIG. 7 shows a pixel 300 with a pinned photodiode (PPD) 301 that collects photon generated charge. The PPD may be coupled to a special charge overflow circuit 350 (similar to as in FIG. 5) that includes transistor 306 with the implanted threshold shift Vtx 309, the overflow charge accumulation capacitor C_{OF} 308, and reset transistor 307. The PPD may be further coupled to the global charge transfer transistor 302, the FD node 310, and the source follower (SF) transistor 304 gate. The transfer transistor 302 may also serve as an antiblooming device directing the antiblooming charge to the drain bias line 315 through the reset transistor 303. The FD node 310 may be reset by the reset transistor 303 to the Vdd bias line 315. The drain of the SF transistor 304 may also be connected to the Vdd bias line 315. The source of the SF transistor 304 may be connected to hybrid bond pad 311 that provides connection to the circuits on the carrier chip. The aforementioned circuit components are located on the top chip 338 (e.g., an upper chip similar to upper chip 42 in FIG. 2) and are supplied with the corresponding driving signals delivered through the lines 314, 315, 316, 317, and 357.

The pixel circuit further includes components located on the carrier chip such as transistors 318 and 319 that direct the reference signal and the photodiode charge induced signal to the storage capacitors 320 and 321. The transistors may also be activated when the transistor 305 is turned off and the voltage signal from the capacitors 320 and 321 is supplied through the SF transistor 322 and the row addressing transistor 323 to the column sense line 324. The column sense line 324 may supply the bias current to the SF 322 from the current source 325 and deliver the pixel signals to the ADC located at the periphery of the chip together with the current source 325. The correlated double sampling (CDS) signal processing scheme is implemented in the ADC circuits where the pixel reference signal is subtracted from the photon induced signal thereby removing the pixel FD reset kTC noise. The controlling signals and the bias to the devices located on the carrier chip are supplied through the lines 312, 313, 315, 326, 327, and 339.

The operation of these pixel circuits may again be better understood from the timing diagram provided in FIG. 8. The diagram consists of two main sections: the global pulses section 336 and the frame charge integration section 337 that also includes the signal readout section. The signal readout section may be shorter than the charge integration section. For simplicity the timing diagram shows the readout only from the first row.

Global charge transfer begins by turning the Rs2 line bias low (see trace 328). This turns the reset transistor 303 off and biases the floating diffusion (FD) 310 to a floating state. The bias level of the FD is sensed by the SF transistor 304 with its drain connected to the line 315 that is biased at Vdd. The transistors 318 and 305 are turned on as shown by the traces 331 and 333, which charges up the holding capacitor 320 Ch1 with the reference signal. In the next step, the transfer gate of transistor 302 is pulsed high and low (see trace 330), which globally transfers charge from all the PPDs to the FDs. The bias of the FDs changes and this is sensed by the SF, which charges up the holding capacitor 321 Ch2 to a level determined by the photon generated signal. Charging proceeds through the transistors 305 and 319 that were turned on as is shown by traces 332 and 333. The global shutter timing cycle is completed by turning the transistor 305 off (see trace 333) and applying a pulse to the overflow reset transistor 307 gate (see trace 329). Charging up pulses (see traces 331 and 332) may have a slow rise time in order to minimize the surge current to capacitors, because the capacitors 320 and 321 are charged all in parallel for the whole array.

In the next step, the readout cycle begins by turning the row select transistor 323 on (see trace 335) and the transistor 318 also on (see trace 331). This action supplies the reference signal stored on the capacitor 320 through the source follower (SF) 322 and the row addressed transistor 323 to the column sense line 324. Column sense line 324 is biased by the current source 325 and supplies this signal to the ADC located at the chip periphery. After the signal is transferred to the ADC and stored there or converted to the digital equivalent, the charge holding capacitor 320 Ch1 is discharged by applying pulse to the gate of the transistor 344 (see trace 334). The capacitor 320 Ch1 discharge proceeds through the transistor 318 and transistor 344.

The reference signal readout is followed by the photodiode charge generated signal readout stored on the capacitor 321 Ch2. The photodiode charge generated signal is read out in a similar way as the reference signal. Transistor 319 may be turned on (see trace 332). This action supplies the signal stored on the capacitor 321 through the SF 322 and the row addressed transistor 323 to the column sense line 324. Column sense line 324 supplies this signal again to the ADC located at the chip periphery. After the signal is transferred to the ADC and also stored there or converted to the digital equivalent, the charge holding capacitor 321 Ch2 is discharged by pulsing the gate of the transistor 344 high and low again (see trace 334). The capacitor 321 Ch1 discharge proceeds through the transistor 319 and transistor 344. The CDS signal processing scheme (e.g., subtraction of the reference signal from the FD signal) may be realized in the ADC circuits located at the periphery of the carrier chip.

The above described readout for the first row is followed by the readout of the remaining rows in a row-by-row sequential manner until the whole array has been read out. During this time the next frame of charge is integrated in the PPDs. The readout cycle can be shorter than the charge integration cycle.

Because the capacitor Ch1 320 and Ch2 321 discharge proceeds in a sequential manner, it is not anticipated that large current surges will flow during this process, thereby disturbing the power supply or ground bias line potentials. This is important for preventing the unwanted noise injection into the signal from these chip power line bounces.

The charge overflow circuit consisting of the transistor 306 and the capacitor 308 is serving to remove the majority of the charge (e.g., 90%, more than 60%, more than 75%, more than 80%, more than 90%, etc.) from the pixel PPD in high light level conditions. The remaining charge in the pixel may be used in the signal readout circuits to reconstruct the HDR signal. In the low light level pixel illumination condition, no charge may be removed from the pixel.

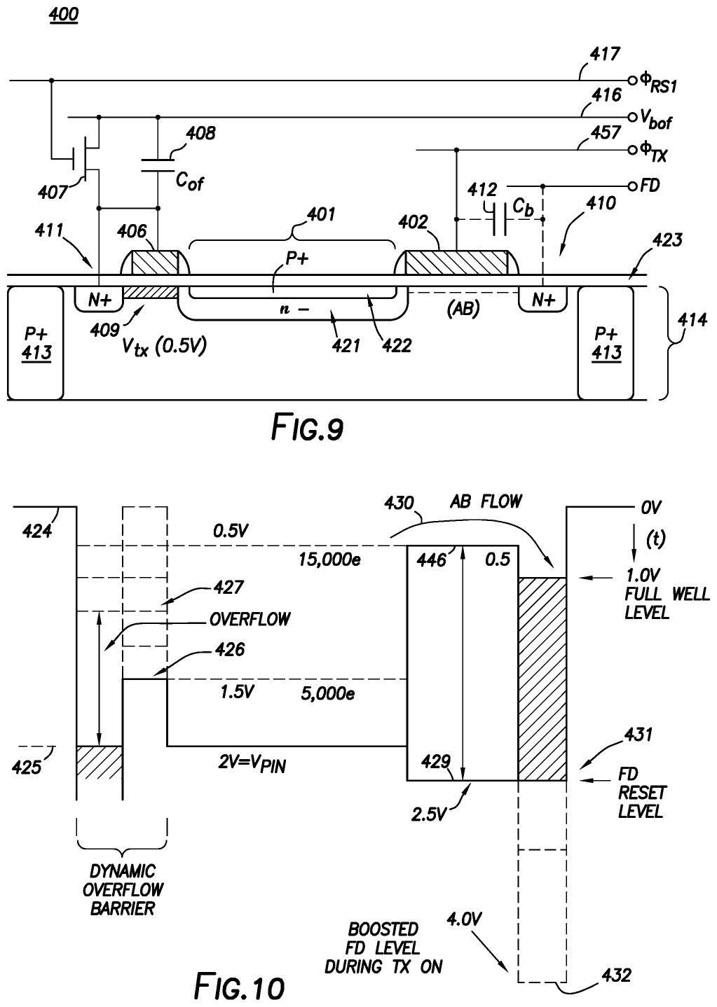

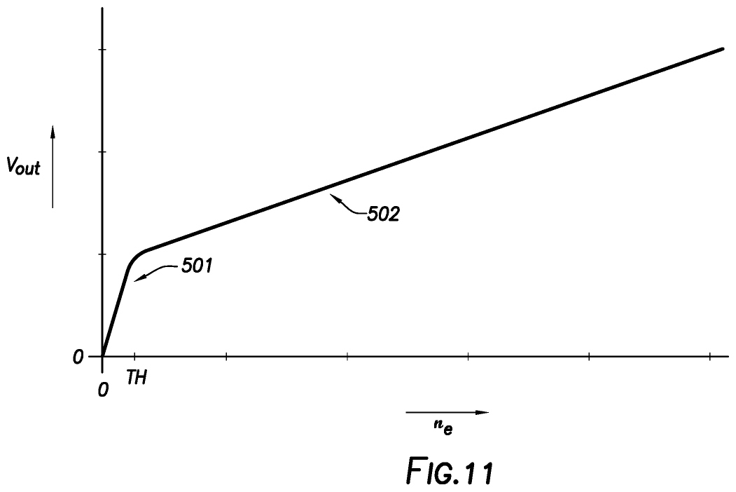

FIG. 9 is a cross-sectional side view of a pixel including that illustrates the dynamic charge overflow (DCO) concept. FIG. 10 is a corresponding potential diagram of the pixel shown in FIG. 9. FIGS. 9 and 10 show the charge overflow barrier, the charge overflow drain, the floating diffusion node that includes boosting during the charge transfer, and the Antiblooming Barrier (AB) under the charge transfer gate that controls pixel blooming. Alternatively, transistor 407 may be used for blooming control instead of transistor 402 when suitable biases are applied to its gate and drain.

As shown in FIG. 9, pixel 400 includes a pinned photodiode (PPD) region 401 with an adjacent charge transferring gate 402. The charge transferring gate 402 may transfer charge from the pinned photodiode to adjacent floating diffusion (FD) region 410. A wire connection may couple the floating diffusion region to the source follower (SF) transistor. The pixel is integrated in the top chip substrate region 414. Substrate region 414 may have a front surface at a front side of the substrate and a back surface at a backside of the substrate. Charge transferring gate 402 is formed on the front side of the substrate, for example. Incident light may pass through the backside of the substrate to reach the pinned photodiode. The dynamic overflow barrier transistor 406 is adjacent to the PPD and controls the charge overflow amount. The pixel cross section includes the overflow transistor drain 411, the pixel channel stop regions 413, the PPD implants 421 and 422, the gate oxide 423, the reset transistor 407, and the overflow capacitor C_{OF} 408. Control signals may be supplied to the pixel components trough the lines 457, 416, and 417.

As shown in FIG. 10, potential profile 424 may include a potential well 425 under the drain 411 of the overflow transistor 406 and a barrier 426 resulting from the implant 409 under the gate of the transistor 406. As one example, the potential well level under the PPD may be approximately 2.0V and can store approximately 5000 e before electrons starts spilling over the barrier 426 into the drain well 425. This means that no integrated charge below 5000 e is lost to the overflow.

After the amount of accumulated charge in the PPD becomes larger than 5000 e, charge starts spilling over to the drain well 425 and the drain well may be reduced in a rate that depends on the value of the overflow capacitor C_{OF}. This is shown by the reduced barrier potential level 427. For example, for a C_{OF} capacitor of 16.0 fF the charge conversion rate to the pixel output voltage is approximately 10 uV/e while the charge conversion rate before the overflow is 100 uV/e. This results in a 10:1 signal compression above the overflow threshold, thereby allowing detection of 105,000 e in a 15,000 e PPD well. Once 5,000 e are in the PPD well, each subsequent electron is indicative of 10 generated electrons (e.g., 5,000 e+10×10,000 e=105,000 e). The drawing also shows the transfer gate 402 with its potential 429 at the on level and the potential 446 at the off level. During the charge transfer (when the transfer transistor is being turned on) it may be useful to boost up the FD potential from the level 431 to the level 432 in order to transfer all charge from the PPD to the FD. The boosting can be accomplished by several ways. One possibility (shown in FIG. 9) is by using a boosting capacitor C_{b} 412 connected between the Tx gate 402 and the FD.

When the TX gate 402 is turned off, a potential under this gate does not have to be zero. It may be advantageous to leave some residual potential barrier there by design (e.g., 0.5 V) for the blooming overflow current to flow to the FD and to the drain when the reset transistor (e.g., reset transistor 303 in FIG. 7) is turned on.

Because approximately only 10% of the high light level illumination charge may be stored in the pixel, the pixel size does not have to be increased. This effectively compresses the pixel dynamic range, which is then recovered in the signal processing circuits. The low light level illumination charge, on the other hand, is not affected by this process, which preserves the pixel high sensitivity and low noise without compromising the image sensor array resolution.

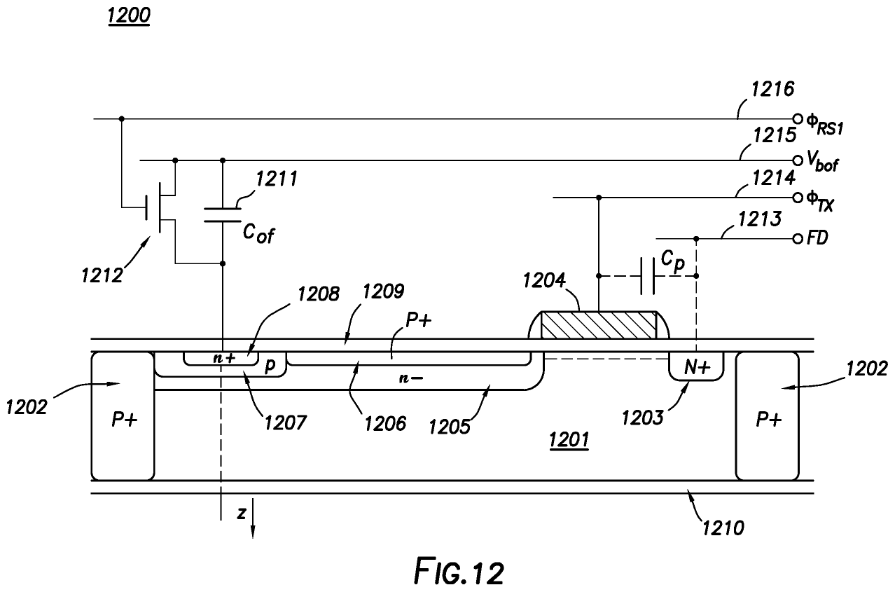

FIG. 11 is a graph of the detected charge versus the output voltage generated by the pixel with the DCO. The graph indicates the two regions of dependency: a first region where the integrated charge is below the threshold TH of the dynamic charge overflow and the dynamic charge overflow is not active and a second region where the dynamic charge overflow is active. As shown in FIG. 11, below threshold TH (which may be 5,000 e, 10,000 e, less than 5,000 e, etc.) the slope of the response is greater than above threshold TH. Threshold TH may be selected by the design for the optimum noise performance using a suitable Vtx implant.

In FIG. 11, the portion of the graph 501 represents the case where no charge is lost from the PPD due to the dynamic charge overflow. The portion of the graph 502 represents the case where there is charge overflow to a capacitor (e.g., C_{OF} in FIGS. 5 and 7). The capacitor may have any desired capacitance (e.g., 16 fF, less than 16 fF, greater than 16 fF, etc.). Any capacitance values and other threshold values may be used to control where charge overflow begins and consequently modify the conversion characteristics of the pixel.

In another possible embodiment, pixels with different capacitor values and different overflow thresholds may be organized into groups of super-pixels or organized in alternate rows of the image sensor array. This type of arrangement may provide additional high dynamic range (HDR) increase without the loss of resolution or sensitivity in low light level illumination conditions. For example, a first imaging pixel of the array of imaging pixels may have a respective first threshold and a second imaging pixel of the array of imaging pixels may have a respective second threshold that is different than the first threshold. In another possible embodiment, a first imaging pixel of the array of imaging pixels may have a respective first charge overflow structure that includes a respective first overflow capacitor with a first capacitance and a second imaging pixel of the array of imaging pixels may have a respective second charge overflow structure that includes a respective second overflow capacitor with a second capacitance that is different than the first capacitance.

In the aforementioned embodiments, all of the transistors may be metal-oxide semiconductor field-effect transistors (MOSFETs). Alternatively, one or more of the transistors may optionally be a junction gate field-effect transistor (JFET) if desired.

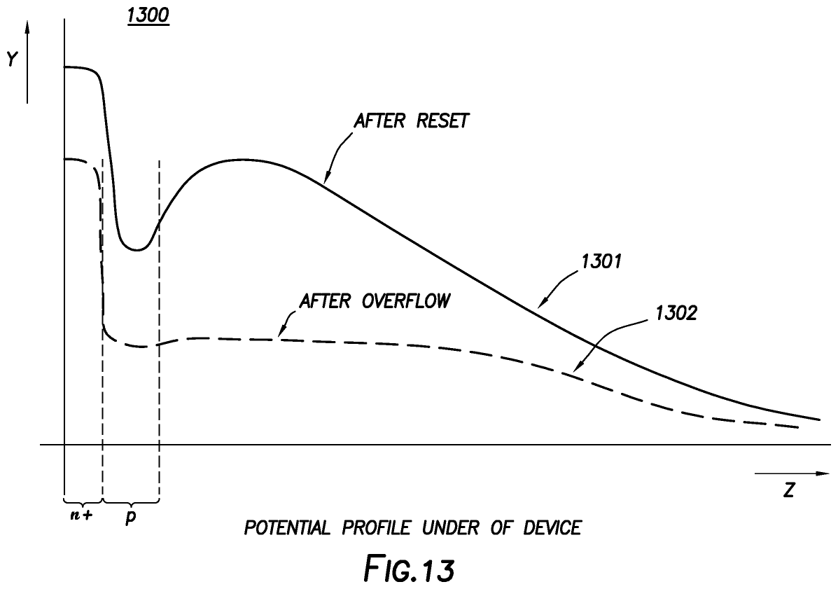

Another possible arrangement for a pixel with a dynamic charge overflow device is shown in FIG. 12. FIG. 13 shows the potential profile that corresponds to the pixel of FIG. 12. As shown in FIG. 12, pixel 1200 may have a back side illuminated silicon bulk substrate 1201. P+ implants 1202 in bulk substrate 1201 may define the boundary of the pixel. It should be noted that P+ implants 1202 may be electrically connected to ground to pin the implants at a constant potential. Floating diffusion (FD) region 1203 is connected to the line 1213 that is further connected the source follower or other signal processing circuits. A pinned photodiode (PPD) is formed by n-diffusion region 1205 and the p+ pinning region 1206. Transfer gate 1204 transfers charge from the pinned photodiode to the floating diffusion.

The dynamic charge overflow device (DCO) is adjacent to the PPD and formed by the p-type implant 1207 and the n+ type implant 1208. The DCO may therefore sometimes be referred to as an n-p-n based overflow device (or a JFET-based overflow device). The region 1208 is also connected to the overflow capacitor Cof 1211 and its reset transistor 1212. A p+ doped region 1210 may be formed on the back of substrate 1201 to minimize the dark current generation by the interface states. Oxide isolation region 1209 may be formed on the front surface of substrate 1201 to isolate the transfer gate 1204 from the substrate. The back side of the substrate 1201 can also be covered by a protective oxide layer, color filter layer, microlens, etc. The signals are supplied to the various regions and devices of the pixel through the row lines 1213, 1214, 1215 and 1216.

The potential profile under the dynamic charge overflow (DCO) device is shown in FIG. 13. The potential profile is precisely determined by the implanted dopants and it is not affected by the interface states charge. This ensures pixel uniformity across the sensor. The potential profile diagram 1300 after the Cof reset is shown by trace 1301. The potential profile during the overflow is shown by trace 1302. The pixel charge to voltage relation in the overflow exposure region is determined by the value of the Cof capacitor.

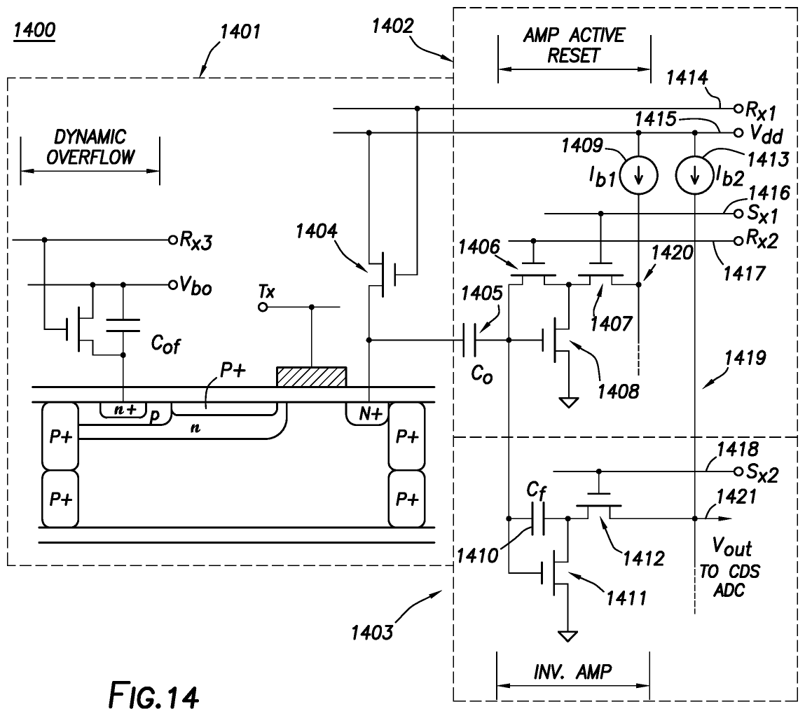

FIG. 14 is a simplified cross-sectional side view with associated circuit diagrams of an illustrative pixel that includes a dynamic charge overflow device of the type shown in FIG. 12. Pixel block 1401 also includes floating diffusion reset transistor 1404 and a coupling capacitor Co 1405. Coupling capacitor Co 1405 may serve as a level shifter. Coupling capacitor 1405 may be used to transfer the signal from the floating diffusion to the input of the inverting amplifier and to the input of the active reset circuits (because they may operate with different DC bias levels and a different gain). Section 1402 represents the pixel active reset circuits. The active reset circuits include an inverting amplifier transistor 1408, reset transistor 1406, and row addressing transistor 1407. Column bias line 1420 provides the constant current bias for this active reset amplifier from the current source 1409 that is located at the periphery of the array. The signal processing inverting amplifier is located in block 1403 and includes a signal inverting transistor 1411, feedback capacitor 1410 Cf, and row addressing transistor 1412. The bias for this amplifier is provided by the current source 1413 through the column bias line 1419, which is again located at the periphery of the array. Both the current sources 1409 and 1413 should be approximately matched in order to supply the same currents to both the active pixel reset circuits and to the inverting amplifier circuits. The signal output 1421 is available on the column line 1419 and supplies signals to the ADC converter. Signal lines 1414, 1416, 1417, and 1418 provide the required pulses to operate the circuits and the Vdd line 1415 supplies the necessary DC bias for these circuits.

To operate the pixel of FIG. 14, all the pixels may first be reset in a rolling fashion (e.g., row-by-row) by activating the active reset circuits. This also includes the floating diffusion resets. This step is followed by applying a global shutter charge transfer pulse to the transfer gates of all the pixels of the array. After that, the outputs of the amplifiers are scanned again in a row by row fashion immediately followed by an active reset. Both the charge induced signal and the reset signal are transferred to the ADC converters located at the array periphery (not shown in the diagram) and processed to remove the pixel-to pixel non-uniformities. This is similar to the CDS signal processing scheme but in a reverse order.

In various embodiments, an image sensor may include an array of imaging pixels, with at least one imaging pixel collecting charge in a respective photodiode. The at least one pixel may have a dynamic charge overflow structure that is coupled to and adjacent to the photodiode that is capable of diverting overflow charge away from the photodiode charge storage well after a predetermined threshold is reached while collecting all change below this threshold.

The dynamic charge overflow structure may include overflow n-p-n doped regions, an overflow charge holding capacitor, and a reset transistor. The overflow n-p-n doped region may provide a dynamically adjustable barrier for the overflow charge from the photodiode. The dynamically adjustable barrier may depend on the amount of charge that has already overflowed and is stored on the overflow capacitor. The overflow capacitor may be reset by the reset transistor.

The imaging pixel may also include a floating diffusion junction coupled to the photodiode through the charge transfer transistor and corresponding reset transistor coupled to the floating diffusion junction. The floating diffusion junction may further be coupled through a level shifting capacitor to the input of an active reset circuit and to the input of an inverting amplifier circuit. The photodiode may be a pinned photodiode. The active reset circuit may include an inverting gain amplifier. A reset transistor may be connected between the amplifier input and the amplifier output and the row addressing transistor may be connected between the amplifier output and the column current bias line.

The inverting amplifier circuit may include an inverting gain transistor, a feedback capacitor connected between the amplifier input and the amplifier output, and a row addressing transistor connected between the amplifier output and the column current bias line. The pixel reset transistor and the active reset circuit transistors may both be activated at the same time. The signal from the inverting amplifier that is responding to the collected charge globally transferred on the floating diffusion may be detected first, followed by the signal from the inverting amplifier after the active reset has been applied. The signal from the inverting amplifier after the active reset has been applied may be subtracted from the signal responding to the collected charge. The signal subtraction may be implemented in a row-by-row fashion.

The active reset may be activated in a row-by-row fashion to the pixels of the array prior to the application of the global charge transfer. The array may be illuminated from the back side and may have a color filter and microlens formed over the imaging pixel on the back side.

It is possible to use an n-type doped substrate for the pixel and reverse the polarity of all the junctions between n-type and p-type. This possibility will not be described in any further detail, but it should be understood that it is included herein.

The foregoing is merely illustrative of the principles of this invention and various modifications can be made by those skilled in the art without departing from the scope and spirit of the invention.

What is claimed is:

1. An image sensor that includes an array of imaging pixels, wherein an imaging pixel of the array of imaging pixels comprises:
a photodiode configured to generate charge in response to incident light, wherein the photodiode comprises a n-diffusion region and a p+ implant in a bulk semiconductor substrate;
a floating diffusion region;
a transfer transistor configured to transfer charge from the photodiode to the floating diffusion region;
an overflow capacitor having first and second plates; and
a junction gate field-effect transistor based overflow device having an n+ implant and a p-type implant, wherein the n+ implant is connected to the second plate of the overflow capacitor.

2. The image sensor defined in claim 1, wherein the imaging pixel further comprises:
a reset transistor having a first terminal coupled to the first plate of the overflow capacitor and a second terminal coupled to the second plate of the overflow capacitor.

3. The image sensor defined in claim 2, wherein the second terminal of the reset transistor is coupled to a node between the second plate and the n+ implant.

4. The image sensor defined in claim 1, wherein the p-type implant is interposed between the n+ implant and the n-diffusion region.

5. The image sensor defined in claim 1, wherein the p-type implant is adjacent to the p+ implant of the photodiode.

6. The image sensor defined in claim 1, wherein all charge below a threshold is collected in a charge storage well of the photodiode and wherein the junction gate field-effect transistor based overflow device diverts some of the charge above the threshold away from the charge storage well of the photodiode.

7. The image sensor defined in claim 6, wherein the junction gate field-effect transistor based overflow device provides a dynamically adjustable barrier for the charge above the threshold and wherein the dynamically adjustable barrier is dependent on an amount of charge on the overflow capacitor.

8. The image sensor defined in claim 1, further comprising:
a first substrate, wherein the photodiode, the floating diffusion region, and the transfer transistor of the imaging pixel are formed in the first substrate; and
a second substrate, wherein the imaging pixel further comprises:
a metal interconnect layer between the first and second substrates;
a reset transistor coupled to the floating diffusion region, wherein the reset transistor is formed in the first substrate; and
a source follower transistor in the first substrate that is coupled to metal interconnect layer.

9. The image sensor defined in claim 8, wherein the imaging pixel comprises:
a first storage capacitor in the second substrate;
a second storage capacitor in the second substrate;
a first transistor in the second substrate that is interposed between the first storage capacitor and the metal interconnect layer; and
a second transistor in the second substrate that is interposed between the second storage capacitor and the metal interconnect layer.

10. The image sensor defined in claim 9, wherein the first storage capacitor is configured to store a reset voltage associated with a reset level of the floating diffusion region and wherein the second storage capacitor is configured to store a signal voltage associated with a signal level of the floating diffusion region.

11. The image sensor defined in claim 10, wherein the imaging pixel further comprises:
an additional source follower transistor in the second substrate; and
a row select transistor in the second substrate coupled between the additional source follower transistor and a column line, wherein the first storage capacitor is coupled to a gate of the additional source follower transistor through the first transistor and wherein the second storage capacitor is coupled to the gate of the additional source follower transistor through the second transistor.

12. The image sensor defined in claim 11, further comprising:
processing circuitry at a periphery of the image sensor configured to perform correlated double sampling using the reset voltage from the first storage capacitor and the signal voltage form the second storage capacitor.

13. The image sensor defined in claim 9, wherein the imaging pixel further comprises:
an additional transistor in the first substrate that is interposed between the source follower transistor and a pre-charge drain bias line.

14. The image sensor defined in claim 9, wherein each imaging pixel further comprises:
a third transistor in the second substrate that is interposed between the metal interconnect layer and the first and second transistors.

15. The image sensor defined in claim 14, wherein the imaging pixel further comprises:
a fourth transistor in the second substrate that is interposed between the third transistor and a ground node.

16. An image sensor that includes an array of imaging pixels, wherein an imaging pixel of the array of imaging pixels comprises:
a photodiode configured to generate charge in response to incident light;
a floating diffusion region;
a transfer transistor configured to transfer charge from the photodiode to the floating diffusion region; and
a charge overflow structure coupled to the photodiode, wherein the charge overflow structure comprises a junction gate field-effect transistor and a capacitor, wherein all charge below a threshold is collected in a charge storage well of the photodiode, and wherein the charge overflow structure diverts some of the charge above the threshold away from the charge storage well of the photodiode.

17. The image sensor defined in claim 16, wherein the junction gate field-effect transistor has an n+ implant and a p-type implant.

18. The image sensor defined in claim 17, wherein the capacitor has first and second plates and wherein the n+ implant is connected to the second plate of the overflow capacitor.

19. An image sensor that includes an array of imaging pixels, wherein an imaging pixel of the array of imaging pixels comprises:
a photodiode configured to generate charge in response to incident light, wherein the photodiode comprises a n-diffusion region and a p+ implant in a bulk semiconductor substrate;
a floating diffusion region;
a transfer transistor configured to transfer charge from the photodiode to the floating diffusion region;
an overflow capacitor having first and second plates; and
an n+ implant in the bulk semiconductor substrate, wherein the n+ implant is connected to the second plate of the overflow capacitor; and
a p-type implant, wherein the p-type implant is interposed between the n+ implant and the n-diffusion region.

20. The image sensor defined in claim 19, wherein the p-type implant is adjacent to the p+ implant of the photodiode.
